(19) United States
(12) Patent Application Publication
(10) Pub. No.: US 2009/0130864 A1
(43) Pub. Date: May 21, 2009

(54) SYSTEMS AND METHODS FOR FLASH ANNEALING OF SEMICONDUCTOR DEVICES

(76) Inventors: Narendra Singh MEHTA, Dallas, TX (US); Perry Howard Shields, Wylie, TX (US); Amitabh Jain, Allen, TX (US)

Correspondence Address: TEXAS INSTRUMENTS INCORPORATED, P O BOX 655474, M/S 3999, DALLAS, TX, 75265, US

(21) Appl. No.: 11/942,367

(22) Filed: Nov. 19, 2007

(51) Int. Cl. H01L 21/02; F27D 11/00

(52) U.S. Cl. 438/795; 219/392; 219/409; 257/E21.52

(57) ABSTRACT

An embodiment generally relates a method of processing semiconductor devices. The method includes forming a semiconductor device and exposing the semiconductor device to a temperature substantially between 1175 to 1375 degrees Celsius after the formation of a gate dielectric layer. The method also includes annealing the semiconductor device for a period of time.

### FIELD

This invention relates generally to annealing of semiconductor devices, more particularly to systems and methods for flash annealing of semiconductor devices.

### DESCRIPTION OF THE RELATED ART

FIG. 5 illustrates a conventional transistor 500 formed over a semiconductor substrate 505, typically a silicon wafer. The transistor 500 includes silicon trench isolation or field oxide isolation wells 510 to isolate device 520, gate dielectric 530 and an electrode 540. An implant process can provides source/drain dopant to source/drain regions 550. The source/drain dopant may be an n-type dopant such as arsenic (As) or phosphorus (P) when the transistor 500 is nMOS, or a p-type dopant such as boron (B) when the transistor 100 is pMOS. Sidewall spacers 510 partially block the implanting of the source/drain dopant into the source/drain regions 550.

As per conventional process flows, an isolation trench can be formed (see FIG. 5, 510) followed by appropriate wells (see FIG. 5, 550). This process is followed by appropriate implantation steps to set the threshold voltage, Vt, of the NMOS and PMOS transistors. This is followed by formation of the gate dielectric either by oxidation or deposition of dielectric. Conventional processes describe that this dielectric can be exposed to a plasma source to incorporate nitrogen or nitrogen can be included in the dielectric during the growth/deposition phase. The dielectric is now annealed in a low oxygen partial pressure environment with temperatures ranging up to 1100 C and for a time within a range of a few seconds.

Nitrogen is introduced as a countermeasure for preventing increase of the gate leak current or B diffusion. This countermeasure also has disadvantages and drawbacks. For instance, the dielectric grown with these types of nitrided processes still suffers from high leakage and large nitrogen content at the interface. Accordingly, it is critical to maintain low leakage current and flat nitrogen profiles, i.e., low nitrogen concentrations at the interface for nitrided dielectrics.

### SUMMARY

An embodiment generally relates a method of processing semiconductor devices. The method includes forming a semiconductor device and exposing the semiconductor device to a temperature substantially between 1175 to 1375 degrees Celsius after the formation of a gate dielectric. The method also includes annealing the semiconductor device for a period of time.

Another embodiment pertains generally to a method of reducing defects in semiconductor devices. The method includes forming a semiconductor device and providing a heat source configured to provide a temperature substantially between 1175 and 1375 degrees Celsius. The method also includes exposing the semiconductor dielectric to the heat source for a period of time right after the formation of the semiconductor dielectric.

Yet another embodiment relates generally to an apparatus for flash annealing of gate dielectrics. The apparatus includes a heat source configured to provide a temperature substantially between 1175 and 1375 degrees Celsius and a carrier means configured to support a semiconductor device. The apparatus also includes a controller configured to move the carrier means within proximity of the heat source to anneal the semiconductor device at the temperature for a period of time substantially within the range of 1 to 10 milliseconds.

### BRIEF DESCRIPTION OF THE DRAWINGS

Various features of the embodiments can be more fully appreciated, as the same become better understood with reference to the following detailed description of the embodiments when considered in connection with the accompanying figures, in which:

FIG. 1A-E collectively illustrate a process flow with a flash anneal in accordance with an embodiment;

FIG. 2 depicts a system for flash anneal in accordance with an embodiment;

FIG. 3A-B each illustrates a scan pattern for an optical light source;

FIG. 4 depicts a second system for flash anneal in accordance with another embodiment; and

FIG. 5 illustrates a conventional transistor.

### DETAILED DESCRIPTION OF EMBODIMENTS

For simplicity and illustrative purposes, the principles of the present invention are described by referring mainly to exemplary embodiments thereof. However, one of ordinary skill in the art would readily recognize that the same principles are equally applicable to, and can be implemented in, all types of semiconductor processing techniques, and that any such variations do not depart from the true spirit and scope of the present invention. Moreover, in the following detailed description, references are made to the accompanying figures, which illustrate specific embodiments. Electrical, mechanical, logical and structural changes may be made to the embodiments without departing from the spirit and scope of the present invention. The following detailed description is, therefore, not to be taken in a limiting sense and the scope of the present invention is defined by the appended claims and their equivalents.

Embodiments pertain generally to systems and method for annealing semiconductor devices. More particularly, semiconductor devices are annealed in a flash anneal system. The flash anneal system can be configured to flash anneal the semiconductor device, where the flash anneal is an exposure of the semiconductor device to substantially higher temperatures than current annealing temperatures for a brief period of time substantially between 1 microseconds to 200 seconds. The high temperature exposure can reduce interface traps and improve gate dielectric properties without increasing the equivalent oxide thickness. The flash anneal can be implemented with an optical energy source such as a laser, an arc lamp, or in a high-temperature oven.

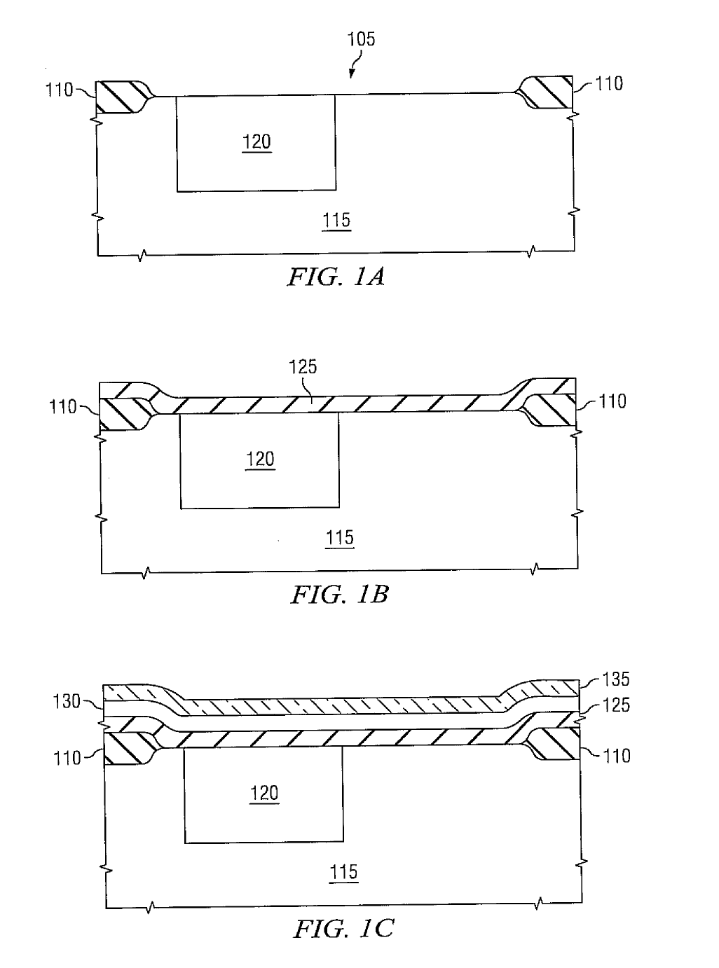

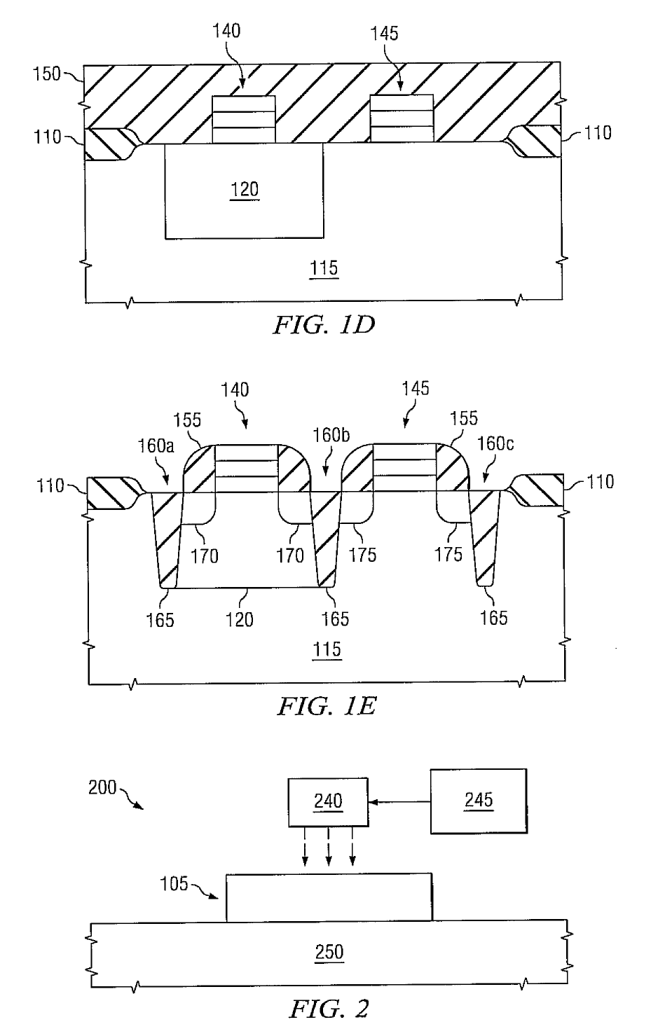

FIG. 1A-E, collectively, illustrate an exemplary processing flow 100 for a semiconductor device 105 in a side view in accordance with an embodiment. It should be readily apparent to those of ordinary skill in the art that the process flow 100 shown in FIG. 1A-E represent a generalized process and that other steps can be added or existing steps can be removed or modified while still remaining within the spirit and scope of the appended claims.

As shown in FIG. 1A, a field oxide layer 110 can be formed on a silicon substrate such as a silicon wafer, to isolate a defined active region and to form a well at a predetermined position. For example, on a P-type silicon substrate 115, a predetermined position defined by photoresist is implanted with N-type impurities using thermal diffusion, whereby an N-well 120 is formed.

As shown in FIG. 1B, after an implantation process (not shown) for implanting impurities to set a threshold voltage, Vₜ, a gate dielectric layer 125. Subsequently, the gate dielectric layer 125 is exposed to a flash/laser anneal process. More particularly, the to substantially higher temperatures than current annealing temperatures for a brief period of time substantially between 1 msec and 100 sec and at a temperature substantially between 1175 and 1375 degrees Celsius. The high temperature exposure can reduce interface traps and improve gate dielectric properties without increasing the equivalent oxide thickness. The laser/flash anneal can be implemented with an optical energy source such as a laser or in a high-temperature oven.

As shown in FIG. 1C, a polysilicon layer 130 and a silicide layer 135 are deposited in sequence. For example, the polysilicon layer 130 can be deposited to a thickness of about 500 A to 3000 A by using low-pressure chemical vapor deposition (LPCVD), and is heavily doped with N-type or P-type impurities by thermal diffusion or implantation. Then, the silicide layer 135 is deposited thereon, where silicide layer 135 can be a tungsten silicide layer.

As shown in FIG. 1D, after defining the pattern of CMOS gate electrodes by a lithographic technique and dry etching, the gate electrodes 140 and 145 are formed and in the meantime their resistivity is reduce by annealing. Finally, an insulating layer 150 such as a silicon nitride layer is deposited.

As shown in FIG. 1E, the silicon nitride layer 150 has been etched back whereby spacers 155 are formed, each to a length of about 1 to 3 microns, on the side walls of the gate electrodes 140 and 145, slits 160a and 160c are left at the margin between the field oxide layer 131 and the spacers 155 adjacent thereto at the outer sides of the gate electrodes 140 and 145, and slit 160b is left between the mutually adjacent spacers 155 at the inner opposing sides of the gate electrodes 140 and 145. Using the field oxide layer 110, the spacers 155 and the gate electrodes 140, 145 as masks, trenches 165 are formed by anisotropic dry etching to a depth of about 2 to 4 microns in the slits 160a, 160c between the field oxide layer 110 and the outer spacers 155, and in the slit 160b between adjacent inner spacers 155 on the edge of the active region adjacent to the well 120 using thermal oxidation or chemical vapor deposition (CVD), trenches 165 are refilled with an oxide layer and etched back. Then the spacers 155 are removed.

Finally, the N-well 120 is then coated by photoresist, and using the gate electrode 140 as a mask, P-type impurities are implanted to form source-drain electrodes 170, so that a PMOS structure is provided. Moreover, the PMOS structure is coated by photoresist, and using the gate 145 as a mask, N-type impurities are implanted to form source-drain electrodes 175, whereby an NMOS structure is provided. Deposition and a flow of boron phosphorus silicon glass (BPSG), a formation of a contact window, metallization, and a deposition of a passivation layer are performed in sequence, whereby the process of trench isolation in the MOS transistor is completed. The above-mentioned PMOS or NMOS structures can be provided by a lightly doped drain (LDD) process.

As a final step (not shown), the semiconductor device 105 is passivated and openings to the bond pads are etched to allow for wire bonding. Passivation can protect the silicon surface against the ingress of contaminants that can modify circuit behavior in deleterious ways.

FIG. 2 depicts the flash anneal device 200 as described with respect to FIG. 1B in accordance with an embodiment. It should be readily apparent to those of ordinary skill in the art that the flash anneal device 200 depicted in FIG. 2 represents a generalized schematic illustration and that other components may be added or existing components may be removed or modified.

As shown in FIG. 2, the flash anneal device 200 includes a semiconductor device 105, an optical source 210 and a carrier 250. The semiconductor device 105 can be any type of semiconductor device formed by conventional semiconductor device processing techniques that grows or deposits a gate oxide.

The optical source 240 can be configured to provide a heat source approximately about 1050 to 1375 degree Celsius to the semiconductor device 105 after the formation of the gate dielectric layer 125. In some embodiments, the optical source 240 is configured to raise the temperature at the impact site on the semiconductor device to 1250 degrees Celsius. The optical source 240 can be implemented with a laser, arc lamp, or other similar light generating device. In some embodiments, the wavelength of the laser is 0.1-0.15 micro meters and at a power of 1000-7500 Watts.

The flash anneal device 200 also includes a carrier 250. The carrier 250 can be configured to support the semiconductor devices 105 (typically in the form of a wafer) as the semiconductor devices 105 are being flash annealed.

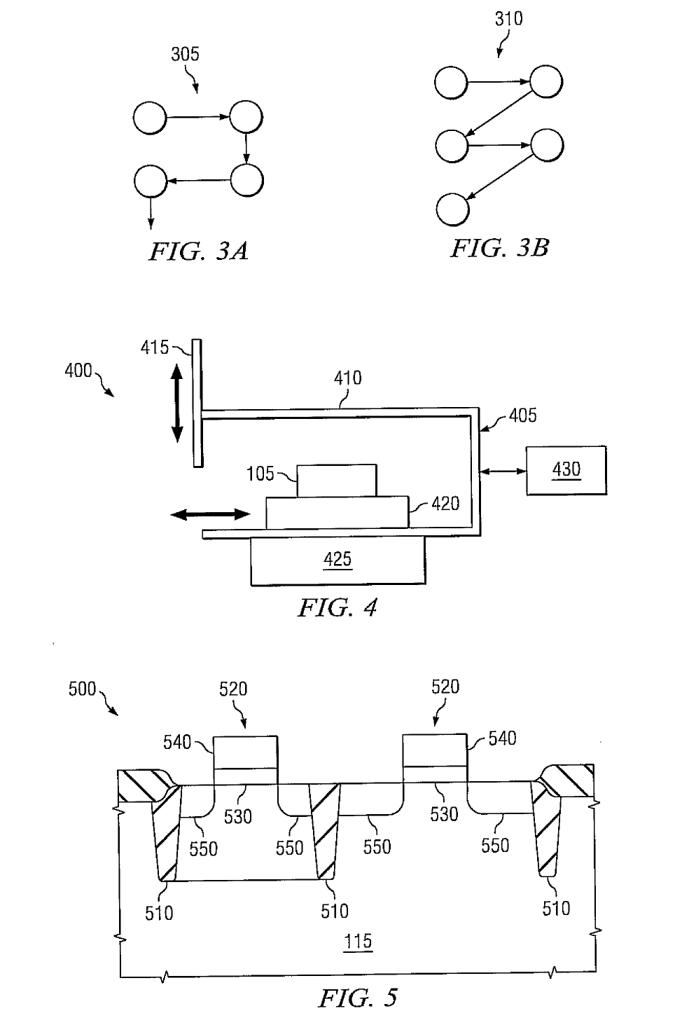

The controller 245 can be configured to direct the path of the light from the optical source 240 onto the semiconductor device 105 supported on the carrier 250. The controller 245 can be configured to scan the semiconductor device 105 in a raster scan pattern as illustrated in FIG. 3A and FIG. 3B. As shown in FIG. 3A, the raster scan pattern 305 is a row-by-row scan of the semiconductor device 105 where the laser is configured to drop one row and return to the other side. As shown in FIG. 3B, the raster scan pattern 310 is also a row-by-row scan but the laser returns to a first position in the next row after completing a row. It should be readily obvious to those skilled in the art that other scan patterns can be used to scan the semiconductor device 105 without departing from the spirit and scope of the claimed invention. Similarly, the optical source 105 can also be configured to encompass the semiconductor device 105 in a single scan.

The controller 245 can also be configured to provide the light from the optical source 240 to stay on a position on the semiconductor device 105 for a period of time substantially between 100 micro seconds to a few seconds to flash anneal the semiconductor device 105. Since the semiconductor device 105 is exposed to a higher temperature over conventional anneal temperatures (e.g., 1100 degrees Celsius) for such a short period of time, the equivalent oxide thickness of the gate oxide 125 of the semiconductor device 105 does not grow, interface traps are reduced and gate dielectric properties are improved while maintaining a flat nitrogen profile for nitrided dielectrics.

FIG. 4 illustrates an oven system 400 for flash annealing semiconductor device 105 in accordance with another embodiment. FIG. 2 and FIG. 4 share a common semiconductor device 105. Accordingly, the description of the common elements is omitted and the description of these elements with respect to FIG. 1 is being relied upon to provide adequate description of the common elements.

As shown in FIG. 4, the oven system 400 includes the semiconductor device 105 and an oven 405. The oven 405 can include an enclosure 410 with a door 415. The oven 405 can also comprise a moveable carrier 420. The moveable carrier 420 can be configured to provide a support mechanism to place wafers containing the semiconductor devices 105. The over 405 further comprises a heat source 425 which is configured to maintain a temperature in the oven 405 at a value substantially between 1150 and 1350 degrees Celsius. In some embodiments, the temperature of the oven 405 can be set to about 1250 degrees Celsius.

The oven system 400 also includes a controller 430. The controller 430 can be couple to the door 415 and the moveable carrier 420. The controller 430 can be configured to bring in wafer containing semiconductor device 105 on the moveable carrier 420 into the enclosure 410 and closing the oven door 415 for a period of time ranging substantially between 1 microseconds to a few (e.g., 200) seconds and return the moveable carrier 420 out of the enclosure 310. Thus, the controller 430 can subject the semiconductor device 105 to a flash anneal.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

While the invention has been described with reference to the exemplary embodiments thereof, those skilled in the art will be able to make various modifications to the described embodiments without departing from the true spirit and scope. The terms and descriptions used herein are set forth by way of illustration only and are not meant as limitations. In particular, although the method has been described by examples, the steps of the method may be performed in a different order than illustrated or simultaneously. Those skilled in the art will recognize that these and other variations are possible within the spirit and scope as defined in the following claims and their equivalents.

What is claimed is:

1. A method of processing semiconductor devices, the method comprising:
forming a semiconductor device;
exposing the semiconductor device after formation of a gate dielectric to a temperature substantially between 1175 to 1375 degrees Celsius; and
annealing the semiconductor device for a period of time substantially within the range of 1 ms to 60 seconds.

2. The method of claim 1, further comprising providing an optical light source to generate the temperature.

3. The method of claim 2, wherein the period of time is substantially between 1 microseconds to 200 seconds.

4. The method of claim 1, providing an oven as a source to generate the temperature.

5. A method of reducing defects in semiconductor devices, the method comprising:
forming a semiconductor device;
providing a heat source configured to provide a temperature substantially between 1175 and 1375 degrees Celsius; and
exposing the semiconductor device to the heat source for a period of time substantially within the range of 1 microsecond to 200 seconds.

6. The method of claim 5, wherein the heat source is an optical light source to generate the temperature.

7. The method of claim 6, wherein the optical light source is a laser at operating wavelength is between 0.1 and 0.15 micrometer and at a power between 1000 to 7500 W.

8. The method of claim 6, wherein the heat source is an oven.

9. The method of claim 8, wherein the period of time is substantially within the range of 1 microseconds to 200 seconds.

10. An apparatus for flash annealing, the apparatus comprising:
a heat source configured to provide a temperature substantially between 1175 and 1375 degrees Celsius;
a carrier means configured to support a semiconductor device; and
a controller configured to move the carrier means within proximity of the heat source to anneal the semiconductor gate dielectric at the temperature for a period of time substantially within the range of 1 microseconds to 200 seconds.

11. The apparatus of claim 10, wherein the heat source is an optical light source.

12. The apparatus of claim 11, wherein the optical light source is a laser having 0.1-15 microns wavelength and 1000-7500 W power.

13. The apparatus of claim 11, wherein the optical light source is an arc lamp.

14. The apparatus of claim 10, wherein the heat source is an oven.
